(19) United States
(12) Patent Application Publication
(10) Pub. No.: US 2024/0297247 A1
(43) Pub. Date: Sep. 5, 2024

(54) SILICON CARBIDE SEMICONDUCTOR DEVICE AND METHOD FOR PRODUCING SAME

(71) Applicant: FUJI ELECTRIC CO., LTD., Kawasaki-shi (JP)

(72) Inventor: Akimasa KINOSHITA, Matsumoto-city (JP)

(73) Assignee: FUJI ELECTRIC CO., LTD., Kawasaki-shi (JP)

(21) Appl. No.: 18/420,247

(22) Filed: Jan. 23, 2024

(30) Foreign Application Priority Data
Mar. 3, 2023 (JP) 2023-033152

(51) Int. Cl. H01L 29/78; H01L 21/04; H01L 29/06; H01L 29/16; H01L 29/66

(52) U.S. Cl. CPC H01L 29/7811; H01L 21/0465; H01L 29/0623; H01L 29/063; H01L 29/1608; H01L 29/66068; H01L 29/7813

(57) ABSTRACT

A silicon carbide semiconductor device includes: drift layer provided over an active portion and a breakdown voltage structure portion, the active portion has: a p-type base region provided in the drift layer; an n-type main region provided on the upper surface side of the base region; a p-type buried region provided in contact with the base region; and a p-type base contact region provided in contact with the main region on the upper surface side of the buried region, the breakdown voltage structure portion has: p-type electric field relaxation regions provided on the upper surface side of the drift layer, each of the main region and the base contact region contains a 3C-structure in at least a part in contact with the main electrode, and the electric field relaxation regions contain a 3C-structure in an upper portion and contain a 4H-structure in a lower portion.

### CROSS-REFERENCE TO RELATED APPLICATION

This application claims benefit of priority under 35 USC 119 based on Japanese Patent Application No. 2023-033152 filed on Mar. 3, 2023, the entire contents of which are incorporated by reference herein.

### BACKGROUND OF THE INVENTION

### 1. Field of the Invention

This disclosure relates to a silicon carbide (SiC) semiconductor device using silicon carbide (SiC) and a method for producing the same.

### 2. Description of the Related Art

JP 2009-49198 A discloses a semiconductor device in which an amorphous layer is formed by ion-implanting phosphorus into a hexagonal single-crystal silicon carbide substrate, heat treatment is performed to recrystallize the amorphous layer into cubic single-crystal n-type silicon carbide, and nickel is deposited on the upper surface of the n-type silicon carbide, forming an electrode.

WO 2017/042963 A1 discloses a semiconductor device having an n⁺-type source region, and an n⁺-type 3C-SiC region and a p⁺-type potential fixing region formed in the n⁺-type source region in an n⁻-type epitaxially-grown layer formed on the first principal surface of an n⁺-type SiC containing 4H-SiC, formed with a barrier metal film in contact with the n⁺-type 3C-SiC region and the p⁺-type potential fixing region, and formed with a source wiring electrode on the barrier metal film.

### SUMMARY OF THE INVENTION

When an avalanche occurs in a breakdown voltage structure portion, there is a possibility that a load is applied to an insulating film covering the breakdown voltage structure portion depending on a path through which a current flows.

In view of the above-described problems, it is an object of this disclosure to provide a SiC semiconductor device capable of suppressing the degradation of the reliability of the breakdown voltage structure portion and a method for producing the same.

To achieve the above-described object, one aspect of this disclosure is a SiC semiconductor device including: an active portion; and a breakdown voltage structure portion provided surrounding the periphery of the active portion in plan view, in which a first conductivity-type drift layer containing silicon carbide is provided over the active portion and the breakdown voltage structure portion, the active portion has: a second conductivity-type base region containing silicon carbide provided on the upper surface side of the drift layer; a first conductivity-type main region containing silicon carbide provided on the upper surface side of the base region; a second conductivity-type buried region containing silicon carbide provided in contact with the base region on the upper surface side of the drift layer; a second conductivity-type base contact region containing silicon carbide provided in contact with the main region on the upper surface side of the buried region; a gate electrode provided with a gate insulating film interposed inside a trench passing through the main region and the base region; and a main electrode provided in contact with the main region and the base contact region, the breakdown voltage structure portion has: a second conductivity-type electric field relaxation region containing silicon carbide provided on the upper surface side of the drift layer; and an insulating film provided on the upper surface of the electric field relaxation region, the main region and the base contact region each contain a 3C-structure in at least a part in contact with the main electrode, and the electric field relaxation region contains a 3C-structure in an upper portion and contains a 4H-structure in a lower portion.

To achieve the above-described object, another aspect of this disclosure is a method for producing a SiC semiconductor device including: forming a first conductivity-type drift layer containing silicon carbide over an active portion and a breakdown voltage structure portion surrounding the periphery of the active portion in plan view; forming a second conductivity-type base region containing silicon carbide on the upper surface side of the drift layer in the active portion; forming a first conductivity-type main region on the upper surface side of the base region, the main region containing silicon carbide and containing a 3C-structure in at least the upper surface side part; forming a second conductivity-type buried region containing silicon carbide to be in contact with the base region on the upper surface side of the drift layer; forming a second conductivity-type base contact region to be in contact with the main region on the upper surface side of the buried region, the base contact region containing silicon carbide and containing a 3C-structure in at least the upper surface side part; forming a trench passing through the main region and the base region; forming a gate electrode with a gate insulating film interposed inside the trench; forming a main electrode to be in contact with the upper surfaces of the main region and the base contact region; forming a second conductivity-type electric field relaxation region containing silicon carbide and containing 3C-structure in an upper portion and containing 4H-structure in a lower portion on the upper surface side of the drift layer in the breakdown voltage structure portion; and forming an insulating film on the upper surface of the electric field relaxation region.

### BRIEF DESCRIPTION OF THE DRAWINGS

FIG. 1 is a plane schematic diagram illustrating an example of a SiC semiconductor device according to a first embodiment;

FIG. 2 is a longitudinal cross-sectional diagram illustrating the cross-sectional configuration as viewed in cross-section along the A-A cut line in FIG. 1;

FIG. 3 is a longitudinal cross-sectional diagram illustrating the cross-sectional configuration of a breakdown voltage structure portion of a SiC semiconductor device according to Comparative Example;

FIG. 4 is a longitudinal cross-sectional diagram illustrating the cross-sectional configuration of a breakdown voltage structure portion of a SiC semiconductor device according to a first embodiment;

FIG. 5 is a cross-sectional schematic diagram for explaining one example of a method for producing a SiC semiconductor device according to the first embodiment;

FIG. 6 is a cross-sectional schematic diagram following FIG. 5 for explaining the one example of the method for producing a SiC semiconductor device according to the first embodiment;

FIG. 7 is a cross-sectional schematic diagram following FIG. 6 for explaining the one example of the method for producing a SiC semiconductor device according to the first embodiment;

FIG. 8 is a cross-sectional schematic diagram following FIG. 7 for explaining the one example of the method for producing a SiC semiconductor device according to the first embodiment;

FIG. 9 is a cross-sectional schematic diagram following FIG. 8 for explaining the one example of the method for producing a SiC semiconductor device according to the first embodiment;

FIG. 10 is a cross-sectional schematic diagram following FIG. 9 for explaining the one example of the method for producing a SiC semiconductor device according to the first embodiment;

FIG. 11 is a cross-sectional schematic diagram following FIG. 10 for explaining the one example of the method for producing a SiC semiconductor device according to the first embodiment;

FIG. 12 is a cross-sectional schematic diagram following FIG. 11 for explaining the one example of the method for producing a SiC semiconductor device according to the first embodiment;

FIG. 13 is a longitudinal cross-sectional diagram illustrating the cross-sectional configuration of a breakdown voltage structure portion of a SiC semiconductor device according to a second embodiment; and

FIG. 14 is a longitudinal cross-sectional diagram illustrating the cross-sectional configuration as viewed in cross-section along the A-A cut line in FIG. 1 of a SiC semiconductor device according to a third embodiment.

### DETAILED DESCRIPTION

Hereinafter, first to third embodiments of this disclosure will be described with reference to the drawings. In the description of the drawings, the same or similar reference numerals are attached to the same or similar parts, and duplicate descriptions are omitted. The drawings are schematic, and the relationship between the thickness and the plane dimension, the thickness ratio of each layer, and the like are different from the actual relationship, ratio, and the like in some cases. Moreover, in some drawings, portions are illustrated with different dimensional relationships and proportions. The first to third embodiments described below exemplify devices or methods for embodying the technical idea of this disclosure. The span of the technical idea is not limited to materials, shapes, structures, and relative positions of elements described herein.

In this specification, a source region of a metal oxide semiconductor field-effect transistor (MOSFET) is “one main region (first main region)” selectable as an emitter region of an insulated-gate bipolar transistor (IGBT). In thyristors, such as MOS-controlled electrostatic induction thyristor (SI thyristor), the “one main region” is selectable as a cathode region. A drain region of the MOSFET is “the other main region (second main region)” of the semiconductor device and is selectable as a collector region in the IGBT and an anode region in the thyristor. When the “main region” is simply referred to in this specification, the “main region” means either the first main region or the second main region, whichever is reasonable from the common general knowledge of those skilled in the art.

The definitions of directions, such as the upper and the lower, in the following description are merely definitions for convenience of description and do not limit the technical idea of this disclosure. It is a matter of course that, when an object is rotated 90° and observed, the upper and the lower are converted to the right and the left in reading, and when the object is rotated 180° and observed, the upper and the lower are reversed in reading, for example. Further, the upper surface” may be read as a “front surface” and the “lower surface” may be read as a “back surface”.

The following description illustrates a case where a first conductivity type is an n-type and a second conductivity type is a p-type. However, the conductivity type may be reversely selected, and the first conductivity type may be a p-type and the second conductivity type may be an n-type. “+” and “−” attached to “n” and “p” mean that semiconductor regions attached with “+” and “−” have impurity concentrations relatively higher or lower than those of semiconductor regions not attached with “+” and “−”. However, it is not meant that, even in semiconductor regions attached with the same “n” and “n”, the impurity concentrations of the semiconductor regions are exactly the same.

In addition, a crystal polymorphism is present in SiC crystals, and main examples include cubic 3C, hexagonal 4H, and hexagonal 6H. As the forbidden band gap at room temperature, a value of 2.23 eV for 3C-SiC, a value of 3.26 eV for 4H-SiC, and a value of 3.02 eV for 6H-SiC are reported. The following description illustrates a case where 4H-SiC and 3C-SiC are mainly used.

### First Embodiment

### <Structure of SiC Semiconductor Device>

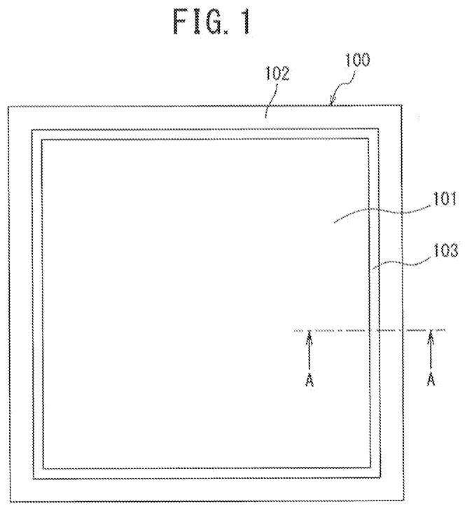

As illustrated in FIG. 1, a SiC semiconductor device (semiconductor chip) 100 according to the first embodiment includes an active portion 101 having a rectangular planar shape and a breakdown voltage structure portion 102 provided surrounding the periphery of the active portion 101 in plan view, for example. The SiC semiconductor device 100 further includes a region 103 provided surrounding the active portion 101 between the active portion 101 and the breakdown voltage structure portion 102 in plan view.

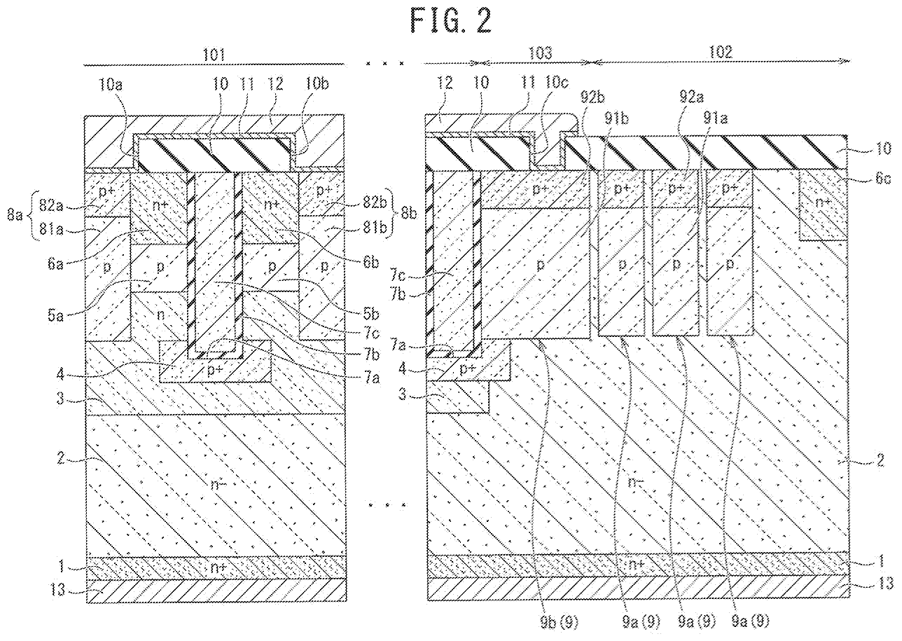

FIG. 2 is a cross-sectional diagram as viewed from the direction indicated by the A-A line in FIG. 1. In FIG. 2, the illustration of a part of the active portion 101 is omitted. As illustrated in FIG. 2, a case is illustrated in which the active portion 101 contains an active element, the region 103 contains a ring region 9b, and the breakdown voltage structure portion 102 contains a plurality of electric field relaxation regions 9a described later as termination structures.

As illustrated in FIG. 2, a case is illustrated in which the SiC semiconductor device 100 contains a trench gate MOSFET as the active element. FIG. 2 illustrates one unit cell containing insulated gate electrode structures (7b, 7c) embedded in a trench 7a, but, in fact, a large number of the unit cells are periodically arranged.

The SiC semiconductor device 100 includes a first conductivity-type (n⁻-type) drift layer 2 provided over the active portion 101, the breakdown voltage structure portion 102, and the region 103. The drift layer 2 contains an epitaxially-grown layer containing SiC, such as 4H-SiC, for example. The drift layer 2 has an impurity concentration in a range of about 1×10¹⁵ cm⁻³ or more and 5×10¹⁶ cm⁻³ or less, for example. The drift layer 2 has a thickness in a range of about 1 μm or more and 100 μm or less, for example. The impurity concentration and the thickness of the drift layer 2 can be adjusted as appropriate according to the breakdown voltage specification or the like.

Over the active portion 101 and the region 103, a first conductivity-type (n-type) current spreading layer (CSL) 3 having an impurity concentration higher than that of the drift layer 2 is selectively provided on the upper surface side of the drift layer 2. The lower surface of the current spreading layer 3 is in contact with the upper surface of the drift layer 2. The current spreading layer 3 is formed by ion implantation of N, for example. The current spreading layer 3 has an impurity concentration in a range of about 5×10¹⁶ cm⁻³ or more and 5×10¹⁷ cm⁻³ or less, for example. The current spreading layer 3 is not necessarily required to be provided. When the current spreading layer 3 is not provided, the drift layer 2 may be provided up to the region of the current spreading layer 3.

In the active portion 101, second conductivity-type (p-type) base regions 5a, 5b are selectively provided on the upper surface side of the current spreading layer 3. The lower surfaces of the base regions 5a, 5b are in contact with the upper surface of the current spreading layer 3. When the current spreading layer 3 is not provided, the lower surfaces of the base regions 5a, 5b are in contact with the upper surface of the drift layer 2. The base regions 5a, 5b are regions containing SiC, in which p-type impurities such as aluminum are ion-implanted into the current spreading layer 3, for example. The base regions 5a, 5b each may be constituted of an epitaxially-grown layer containing SiC, such as 4H-SiC. The base regions 5a, 5b have an impurity concentration in a range of about 1×10¹⁶ cm⁻³ or more and 1×10¹⁸ cm⁻³ or less, for example.

On the upper surface sides of the base regions 5a, 5b, first conductivity-type (n⁺-type) first main regions (source regions) 6a, 6b having an impurity concentration higher than that of the drift layer 2 are selectively provided. The lower surface of the source region 6a is in contact with the upper surface of the base region 5a. The lower surface of the source region 6b is in contact with the upper surface of the base region 5b. The source regions 6a, 6b are regions containing SiC, in which n-type impurities are ion-implanted into the current spreading layer 3, for example. The source regions 6a, 6b have an impurity concentration in a range of about 1×10¹⁹ cm⁻³ or more and 3×10²¹ cm⁻³ or less, for example. The source regions 6a, 6b contain 3C-SiC and 4H-SiC. More specifically, the source regions 6a, 6b each contain a 3C-structure in at least upper surface side part. Hereinafter, 3C-SiC is sometimes referred to as a 3C-structure and 4H-SiC is sometimes referred to as a 4H-structure.

The source regions 6a, 6b have a dimension in the depth direction of 0.5 μm or less. The source regions 6a, 6b may have a dimension in the depth direction of 0.1 μm or more, for example. The proportion of 3C-SiC contained in a part from the upper surface to a depth of 0.3 μm of each of the source regions 6a, 6b is in a range of 50% or more and 100% or less.

The trench 7a is provided which passes through the respective source regions 6a, 6b and the respective base regions 5a, 5b from the upper surfaces of the source regions 6a, 6b in the normal direction with respect to the top surface of the respective source regions 6a, 6b (in the depth direction). The lower surface of the trench 7a reaches the current spreading layer 3. The width of the trench 7a is about 1 μm or less, for example. The source region 6a and the base region 5a are in contact with the left side surface of the trench 7a. The source region 6b and the base region 5b are in contact with the right side surface of the trench 7a. The trench 7a may have a planar pattern extending in a stripe state in the backside direction and in the front direction in the sheet of FIG. 2, or may have a dot-like planar pattern.

The gate insulating film 7b is provided along the lower surface and the side surfaces on both sides of the trench 7a. The gate electrode 7c is provided inside the trench 7a with the gate insulating film 7b interposed. The gate insulating film 7b and the gate electrode 7c implement a trench-gate insulated gate electrode structure (7b, 7c).

Usable as the gate insulating film 7b is a single layer film containing any one film, a composite film obtained by stacking two or more films, or the like of not only a silicon oxide film (SiO₂ film) but a silicon oxynitride (SiON) film, a strontium oxide (SrO) film, a silicon nitride (Si₃N₄) film, an aluminum oxide (Al₂O₃) film, a magnesium oxide film (MgO) film, an yttrium oxide (Y₂O₃) film, a hafnium oxide (HfO₂) film, a zirconium oxide (ZrO₂) film, a tantalum oxide (Ta₂O₅) film, and a bismuth oxide (Bi₂O₃) film. As a material of the gate electrode 7c, a polysilicon layer doped with p-type impurity impurities or n-type impurities with a high impurity concentration (doped polysilicon layer), or high melting point metal, such as titanium (Ti), tungsten (W), or nickel (Ni) is usable, for example.

A gate bottom protection region 4 of the second conductivity-type (p⁺-type) is provided at the bottom of the trench 7a inside the current spreading layer 3. The upper surface of the gate bottom protection region 4 is in contact with the lower surface of the trench 7a. The upper surface of the gate bottom protection region 4 does not have to be in contact with the lower surface of the trench 7a. The gate bottom protection region 4 has an impurity concentration in a range of about 1×10¹⁷ cm⁻³ or more and 1×10¹⁹ cm⁻³ or less, for example. The gate bottom protection region 4 is a region containing SiC, in which p-type impurities are ion-implanted into the current spreading layer 3, for example. The gate bottom protection region 4 is electrically connected to a source wiring electrode 12 in a part, the illustration of which is omitted, and has a function of relaxing an electric field applied to the lower surface of the trench 7a by being depleted when the MOSFET is turned off.

On the upper surface side of the current spreading layer 3, second conductivity-type (p-type) buried regions 81a, 81b are selectively provided in contact with the base regions 5a, 5b, respectively. The lower surfaces of the buried regions 81a, 81b are in contact with the current spreading layer 3. The side surface of the buried region 81a is in contact with the current spreading layer 3 and the base region 5a. The side surface of the buried region 81b is in contact with the current spreading layer 3 and the base region 5b. The buried regions 81a, 81b are regions containing SiC, in which p-type impurities are ion-implanted into the current spreading layer 3, for example. The buried regions 81a, 81b have an impurity concentration in a range of about 5×10¹⁷ cm⁻³ or more and 1×10¹⁹ cm⁻³ or less, for example. The buried regions 81a, 81b are constituted of 4H-SiC.

On the upper surface sides of the buried regions 81a, 81b, p⁺-type base contact regions 82a, 82b are selectively provided respectively, the base contact regions 82a, 82b having an impurity concentration higher than that of the buried region 81a are selectively provided. The lower surface of the base contact region 82a is in contact with the upper surface of the buried region 81a. The side surface of the base contact region 82a is in contact with the source region 6a. The lower surface of the base contact region 82b is in contact with the upper surface of the buried region 81b. The side surface of the base contact region 82b is in contact with the source region 6b. The base contact regions 82a, 82b are regions containing SiC, in which p-type impurities are ion-implanted into the current spreading layer 3, for example. The impurity concentration of the base contact region 82a, 82b is higher than that of the buried regions 81a, 81b and is in a range of about 1×10¹⁹ cm⁻³ or more and 3×10²⁰ cm⁻³ or less, for example. The impurity concentration of the base contact regions 82a, 82b may be lower than that of the source regions 6a, 6b insofar as the concentration is such that transistors can operate. The base contact regions 82a, 82b contain 3C-SiC and 4H-SiC. More specifically, the base contact regions 82a, 82b each contain the 3C-structure in at least upper surface side part.

The base contact regions 82a, 82b have a dimension in the depth direction of 0.3 μm or less. Further, the base contact regions 82a, 82b may have a dimension in the depth direction of 0.05 μm or more, for example. The proportion of 3C-SiC contained in a part from the upper surface to a depth of 0.1 μm of each of the base contact regions 82a, 82b is in a range of 50% or more and 95% or less. The proportion of 3C-SiC contained in each of the base contact regions 82a, 82b may be lower than the proportion of 3C-SiC contained in each of the source regions 6a, 6b. When the base contact regions 82a, 82b contain 3C-SiC, the contact resistance with the source electrodes (11, 12) described later can be suppressed.

In the breakdown voltage structure portion 102, the plurality of second conductivity-type (p-type) electric field relaxation regions 9a is selectively provided on the upper surface side of the drift layer 2. In the example illustrated in FIG. 2, three electric field relaxation regions 9a are provided on the upper surface side of the drift layer 2. The electric field relaxation regions 9a are concentric guard rings (field limiting rings) in plan view, the illustration of which is omitted. The electric field relaxation regions 9a are separated from each other by the drift layer 2. The lower surfaces of the electric field relaxation regions 9a are in contact with the upper surface of the drift layer 2. The electric field relaxation regions 9a are regions containing SiC, in which p-type impurities, such as aluminum, are ion-implanted into the drift layer 2, for example.

The electric field relaxation regions 9a each have a p-type first part 91a and a p⁺-type second part 92a. The second part 92a is an upper portion of the electric field relaxation region 9a and located at a position in the depth direction shallower than the position of the first part 91a. The first part 91a is a lower portion of the electric field relaxation region 9a and has an upper surface in contact with the lower surface of the second part 92a. The impurity concentration of the second parts 92a is in a range of about 1×10¹⁹ cm⁻³ or more and 3×10²⁰ cm⁻³ or less, for example, and is set higher than the impurity concentration of the first parts 91a. By setting the impurity concentration of the first parts 91a, which are located at deeper positions than the positions of the second parts 92a, lower than the impurity concentration of the second parts 92a, the breakdown voltage performance with respect to an electric field of the electric field relaxation regions 9a is improved.

The second parts 92a contain 3C-SiC. The first parts 91a contain 4H-SiC. The second parts 92a contain 3C-SiC and 4H-SiC, and, more specifically, contain 3C-SiC in at least the upper surface side part. The dimension in the depth direction of the second parts 92a is 0.3 μm or less. The dimension in the depth direction of the second parts 92a may be 0.05 μm or more, for example. The proportion of 3C-SiC contained in a part from the upper surface to a depth of 0.1 μm of the second parts 92a is in a range of 50% or more and 95% or less. Thus, the second parts 92a each have a lower proportion of 3C-SiC than that of each of the source regions 6a, 6b. The characteristics of 4H-SiC include crystal defects fewer than those of 3C-SiC and a wider band gap and higher voltage resistance with respect to an electric field than those of 3C-SiC, for example. Additionally, the characteristics of 3C-SiC include ionization energy described below.

As p-type impurities, aluminum and boron are known, for example. The ionization energy of each of the impurities in SiC implanted with the impurities is indicated below. The ionization energy is indicated for each of 3C-SiC and 4H-SiC.
Impurity element/3C-SiC/4H-SiC
Aluminum/250/Hexagonal system: 198, Cubic system: 201
Boron/350/280

This shows that, even in the case of the same impurity element, the ionization energy of the impurity element in 3C-SiC is higher than the ionization energy of the impurity element in 4H-SiC. When the ionization energy of the impurity element is high, the number of holes in SiC decreases and the resistance value of SiC increases. Therefore, when above described p-type impurity element is implanted, the resistance value of 3C-SiC is higher than the resistance value of 4H-SiC. More specifically, the resistance value of the second parts 92a containing 3C-SiC is higher than the resistance value of the first parts 91a containing 4H-SiC.

In the breakdown voltage structure portion 102, a first conductivity-type (n⁺-type) channel stopper region 6c is provided in the outermost periphery of the upper surface side of the drift layer 2. The lower surface of the channel stopper region 6c is in contact with the upper surface of the drift layer 2. The channel stopper region 6c is a region containing 3C-SiC, in which n-type impurities are ion-implanted into the drift layer 2, for example.

In the region 103, a second conductivity-type (p-type) ring region 9b is selectively provided on the upper surface side of the drift layer 2. The lower surface of the ring region 9b is in contact with the upper surface of the drift layer 2. The ring region 9b is a region containing SiC, in which p-type impurities are ion-implanted into the drift layer 2, for example. The ring region 9b is a ring-shaped part surrounding an edge portion of the active portion 101 in plan view, the illustration of which is omitted.

The ring region 9b has a first part 91b and a second part 92b. The second part 92b is located at a position in the depth direction shallower than the position of the first part 91b. The lower surface of the second part 92b is in contact with the upper surface of the first part 91b. The ring region 9b has substantially the same impurity concentration as the impurity concentration of the electric field relaxation regions 9a. The impurity concentration of the second part 92b is in a range of about 1×10¹⁹ cm⁻³ or more and 3×10²⁰ cm⁻³ or less, for example, and is set higher than the impurity concentration of the first part 91b. The second part 92b contains 3C-SiC. The first part 91b contains 4H-SiC. The second part 92b contains 3C-SiC and 4H-SiC, and more specifically, contains 3C-SiC in at least the upper surface side part. The other configurations of the second part 92b are the same as those of the second part 92a.

On the upper surface side of the gate electrode 7c, the upper surface side of the region 103, and the upper surface side of the breakdown voltage structure portion 102, an insulating film 10 is selectively provided. In the breakdown voltage structure portion 102, the insulating film 10 is provided on the upper surfaces of the electric field relaxation regions 9a. More specifically, the insulating film 10 is provided at a position where the insulating film 10 covers the second parts 92a of the electric field relaxation regions 9a. The insulating film 10 is constituted of a single layer film, such as a silicon oxide film doped with boron (B) and phosphorus (P) (BPSG film), a silicon oxide film doped with phosphorus (P) (PSG film), a non-doped silicon oxide film free from phosphorus (P) or boron (B), referred to as “NSG”, a silicon oxide film doped with boron (B) (BSG film), and a silicon nitride film (Si₃N₄ film), or a stacked-layer film thereof, for example. The insulating film 10 is provided with contact holes 10a, 10b to expose the upper surfaces of the source regions 6a, 6b and the base contact regions 82a, 82b. Further, the insulating film 10 is provided with a contact hole 10c to expose the upper surface of the ring region 9b, i.e., the upper surface of the second part 92b.

First main electrodes (source electrodes) (11, 12) are provided to cover the insulating film 10, the upper surfaces of the source regions 6a, 6b and the base contact regions 82a, 82b exposed from the contact holes 10a, 10b, respectively, and the upper surface of the ring region 9b exposed from the contact hole 10c. The source electrodes (11, 12) include the lower-layer barrier metal layer 11 and the upper-layer source wiring electrode 12. For example, the barrier metal layer 11 is constituted of metal, such as titanium nitride (TiN), titanium (Ti), or a TiN/Ti stacked structure with Ti as a lower layer. The barrier metal layer 11 is in direct contact with the source regions 6a, 6b and the base contact regions 82a, 82b, and is in ohmic-contact with the source regions 6a, 6b and the base contact regions 82a, 82b with low resistance. The barrier metal layer 11 is in direct contact with the second part 92b of the ring region 9b and is in ohmic-contact with the second part 92b with low resistance. The upper surfaces of the second parts 92a are covered with the insulating film 10, and therefore the electric field relaxation regions 9a are not in contact with the barrier metal layer 11.

The source wiring electrode 12 is electrically connected to the source regions 6a, 6b, the base contact regions 82a, 82b, and the ring region 9b through the barrier metal layer 11 interposed. The source wiring electrode 12 is provided separately from a gate wiring electrode (illustration of which is omitted) electrically connected to the gate electrode 7c. The source wiring electrode 12 is constituted of metal, such as aluminum (Al), aluminum-silicon (Al—Si), aluminum-copper (Al—Cu), or copper (Cu).

On the lower surface side of the drift layer 2, a first conductivity-type (n⁺-type) second main region (drain region) 1 having an impurity concentration higher than that of the drift layer 2 is provided. The drain region 1 is constituted of a semiconductor substrate (SiC substrate) containing 4H-SiC, for example. The drain region 1 has an impurity concentration in a range of about 1×10¹⁸ cm⁻³ or more and 3×10²⁰ cm⁻³ or less, for example. The drain region 1 has a thickness in a range of about 30 μm or more and 500 μm or less, for example. Between the drift layer 2 and the drain region 1, a dislocation conversion layer or a recombination promotion layer may be provided, which is an n-type buffer layer having an impurity concentration higher than that of the drift layer 2 and an impurity concentration lower than that of the drain region 1.

On the lower surface side of the drain region 1, a second main electrode (drain electrode) 13 is provided. As the drain electrode 13, a single layer film containing gold (Au) or a metal film in which titanium (Ti), nickel (Ni), and Au are stacked in this order from the drain region 1 side is usable, and further a metal film of molybdenum (Mo), tungsten (W), or the like may be stacked on the lowest layer, for example. Further, a drain contact layer, such as a nickel silicide (NiSiₓ) film, for ohmic-contact may be provided between the drain region 1 and the drain electrode 13.

The SiC semiconductor device according to the first embodiment during the operation applies a positive voltage to the drain electrode 13 while using the source electrode (11, 12) as a ground potential, and causes an inversion layer (a channel) to be formed in the respective base regions 5a and 5b toward the side surfaces of the trench 7a so as to be in the ON-state when a positive voltage of a threshold or greater is applied to the gate electrode 7c. In the ON-state, a current flows from the drain electrode 13 toward the source electrode (11, 12) through the drain region 1, the drift layer 2, the current spreading layer 3, the inversion layers of the base regions 5a and 5b, and the source regions 6a and 6b. When the voltage applied to the gate electrode 7c is smaller than the threshold, the SiC semiconductor device is led to be the OFF-state since no inversion channel is formed in the base region 5a or 5b, and no current flows from the drain electrode 13 toward the source electrode (11, 12).

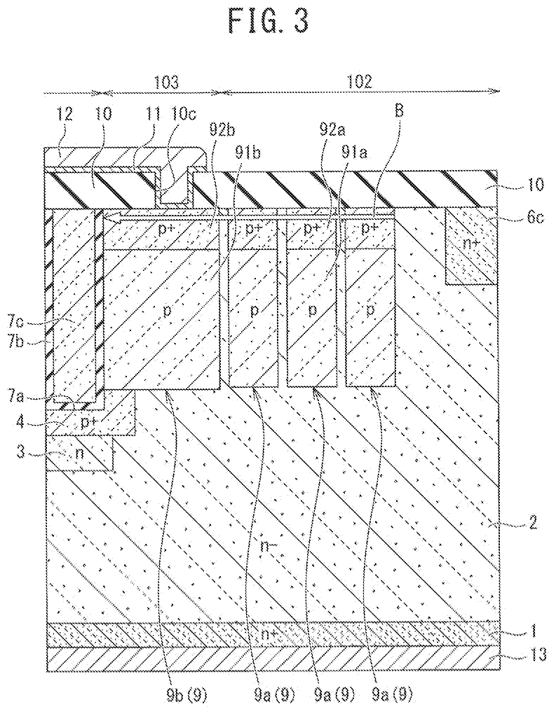

In general, when the electric field relaxation regions 9a and the ring region 9b contain 4H-SiC, electric field concentration in the breakdown voltage structure portion 102 is likely to occur in the upper surface side of SiC, more specifically the contact surface side of SiC with the insulating film 10, as illustrated in FIG. 3. Therefore, a current flowing when an avalanche occurs flows through the upper surface side of SiC as illustrated by the arrow B, which has posed a possibility that a large voltage is applied to the insulating film 10.

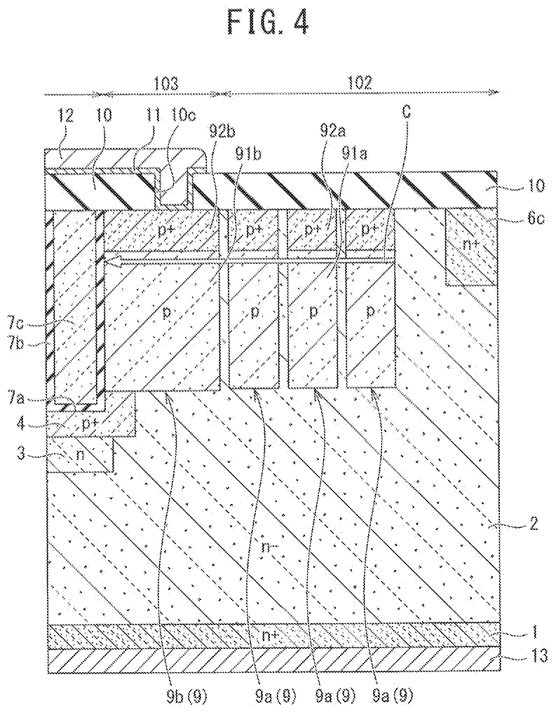

In contrast thereto, according to the SiC semiconductor device of the first embodiment, the electric field relaxation regions 9a contain 3C-SiC in the second parts 92a and contain 4H-SiC in the first parts 91a. Thus, the resistance value of the second parts 92a in contact with the insulating film 10 is larger than the resistance value of the first parts 91a located at deeper positions than the positions of the second parts 92a. Therefore, as illustrated by the arrow C in FIG. 4, a current flowing when an avalanche occurs avoids a 3C-SiC part where the resistance value is high, and flows mainly in 4H-SiC located at a deeper position than the position of 3C-SiC. This can suppress the application of a large voltage to the insulating film 10 of the breakdown voltage structure portion 102, and suppresses the lowering of the reliability of the insulating film 10. Also in the ring region 9b, the lowering of the reliability of the insulating film 10 can be suppressed due to a configuration similar to the configuration of the electric field relaxation regions 9a.

The proportion of 3C-SiC contained in a part from the upper surface to a depth of 0.3 μm of each of the source regions 6a, 6b is in a range of 50% or more and 100% or less. In contrast thereto, in the second parts 92a, the proportion of 3C-SiC contained in the part from the upper surface to a depth of 0.1 μm is in a range of 50% or more and 95% or less, the proportion of 3C-SiC is suppressed, and the depth of a part with a high concentration of 3C-SiC is also kept shallow. Therefore, when compared with the source regions 6a, 6b, the second parts 92a has higher proportion of 4H-SiC whose crystal defects fewer than those of 3C-SiC, and an increase in irregularities of the upper surfaces of the second parts 92a is suppressed. Therefore, even when 3C-SiC has a larger number of crystal defects than those of 4H-SiC, the influence of 3C-SiC on the shape of the upper surfaces of the second parts 92a can be suppressed and an excessive increase in defects generated in the interface between the upper surfaces of the second parts 92a and the insulating film 10 can be suppressed. This can suppress the lowering of the reliability of the breakdown voltage structure portion 102. Further, in the second parts 92a, the depth of the part with a high concentration of 3C-SiC is kept shallow, and therefore a considerable decrease in a region occupied by 4H-SiC having a bandgap wider than that of 3C-SiC can be suppressed. Also in the ring region 9b, the lowering of the reliability of the breakdown voltage structure portion 102 can be suppressed due to a configuration similar to the configuration of the electric field relaxation regions 9a.

In each of the source regions 6a, 6b and the base contact regions 82a, 82b, at least a part in contact with the source electrodes (11, 12) contains 3C-SiC. Therefore, the source regions 6a, 6b and the base contact regions 82a, 82b can ohmic-contact the source electrodes (11, 12) with low resistance without forming a silicide layer of nickel (Ni) silicide or the like. Thus, problems, such as peeling of the silicide layer, can be suppressed as compared with a case where the silicide layer is formed. The source regions 6a, 6b may be shallower than the base contact regions 82a, 82b.

### <Method for Producing SiC Semiconductor Device>

Next, an example of a method for producing a SiC semiconductor device according to the first embodiment will be described. It is a matter of course that the method for producing a SiC semiconductor device described below is an example, and the production can be realized by various other production methods, including modifications of the method, within the meaning of claims.

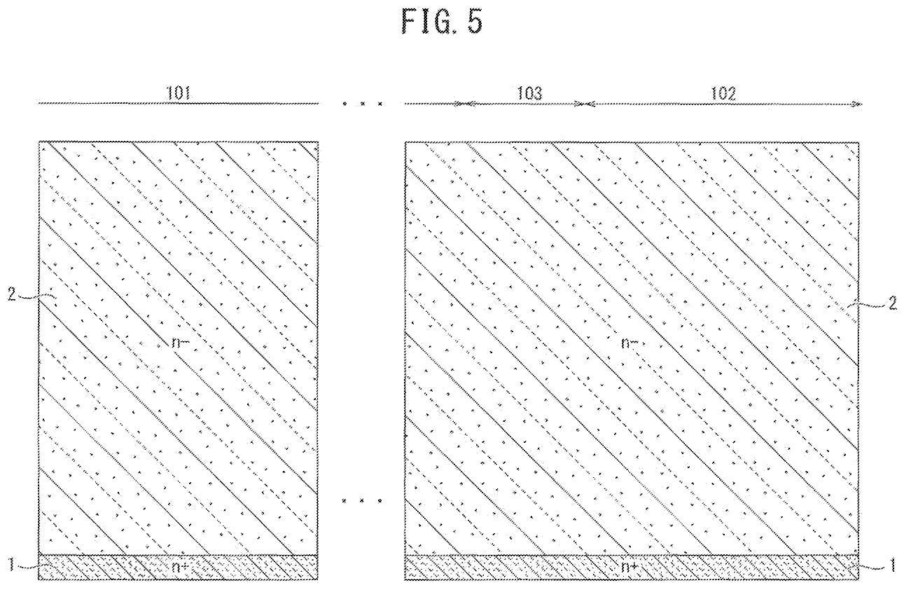

First, a semiconductor substrate (SiC substrate) 1 containing n⁺-type 4H-SiC doped with n-type impurities, such as nitrogen (N), is prepared as illustrated in FIG. 5. The upper surface of the SiC substrate 1 has an off angle of 3° to 8° from the {0001} plane, for example. Then, the drift layer 2 containing n⁻-type 4H-SiC having an impurity concentration lower than that of the SiC substrate 1 is epitaxially grown on the upper surface of the SiC substrate 1, being doped with n-type impurities, such as N.

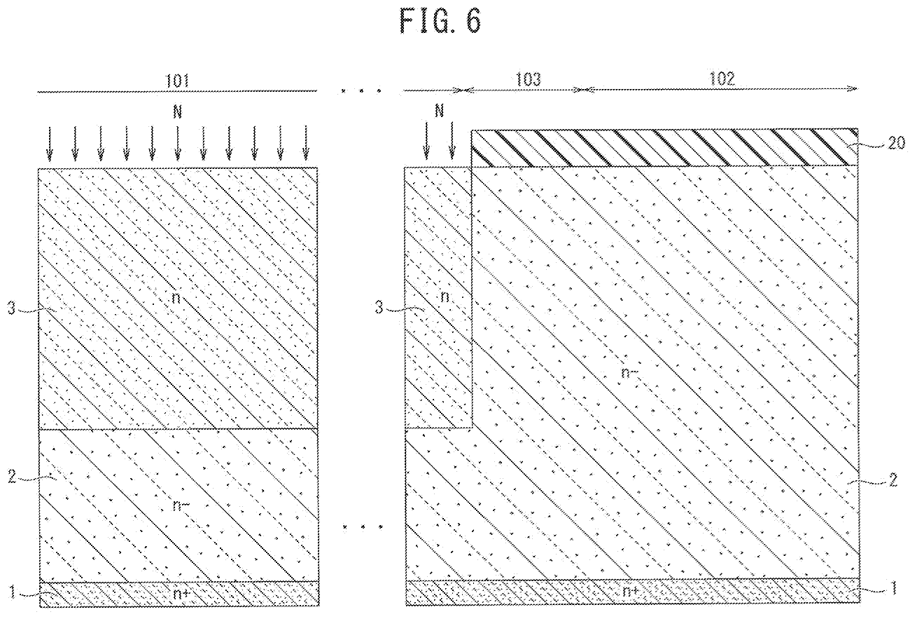

Next, a mask pattern 20 containing a photoresist film is formed on the upper surface of the drift layer 2 using a photolithography technology as illustrated in FIG. 6. Then, n-type impurities, such as nitrogen (N), are ion-implanted into an upper portion of the drift layer 2 using the mask pattern 20 as an ion implantation mask, thereby forming the n-type current spreading layer 3 containing 4H-SiC. Thereafter, the mask pattern 20 is removed. The mask pattern 20 may be a hard mask pattern containing an oxide film, for example.

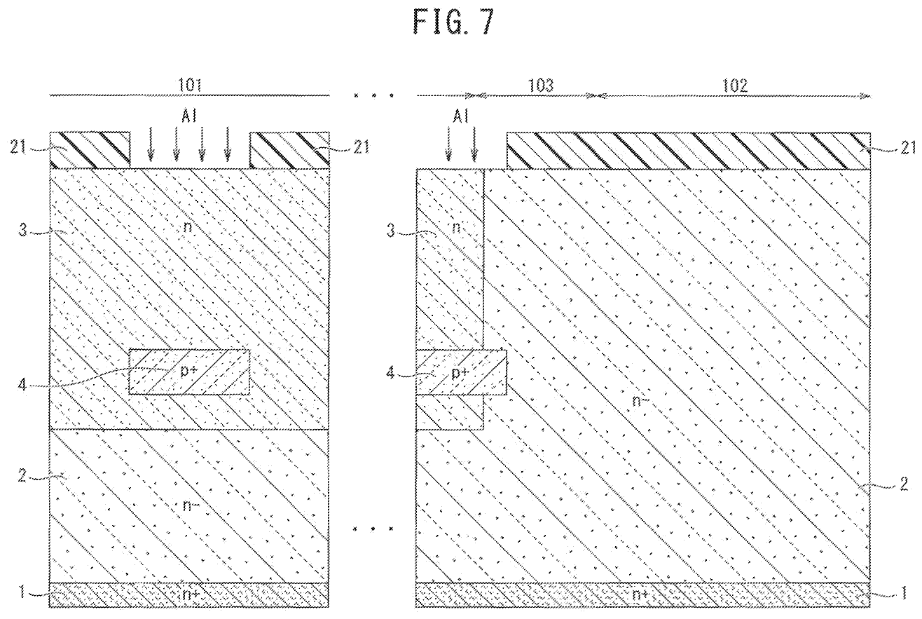

Next, a mask pattern 21 containing a photoresist film is formed on the upper surface of the drift layer 2 as illustrated in FIG. 7. Then, p-type impurities, such as aluminum (Al), are selectively ion-implanted using the mask pattern 21 as an ion implantation mask, thereby selectively forming the gate bottom protection region 4. The ion implantation of aluminum in this case is the implantation into a deeper region, and therefore is performed at a higher acceleration energy in a range of 780 keV or more and 960 keV or less, for example. Thereafter, the mask pattern 21 is removed.

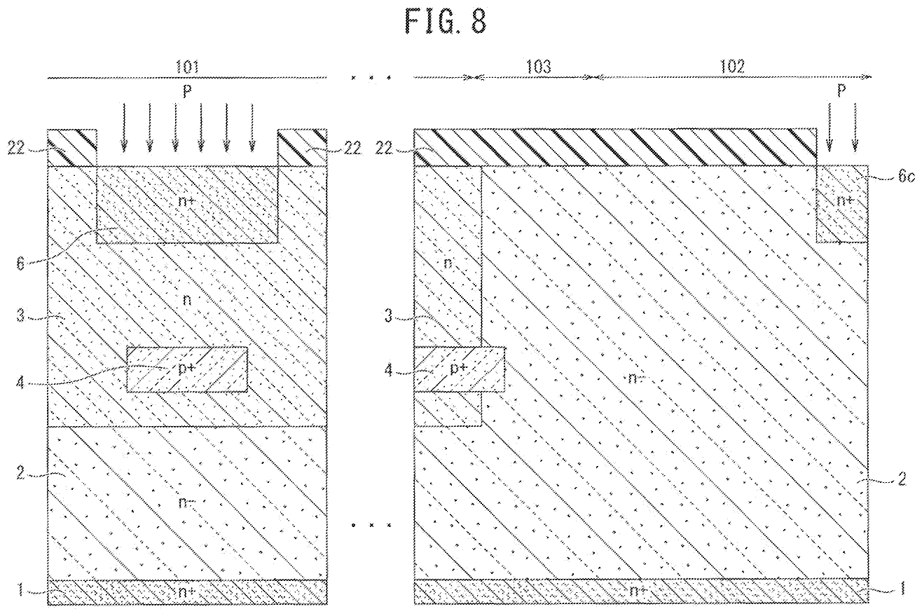

Next, a mask pattern 22 containing a photoresist film is formed on the upper surface of the drift layer 2 as illustrated in FIG. 8. Then, n-type impurities, such as phosphorus (P) or nitrogen (N), are selectively ion-implanted using the mask pattern 22 as an ion implantation mask. As a result, the n⁺-type source region 6 is selectively formed on the upper surface side of the drift layer 2, and the n⁺-type channel stopper region 6c is formed on the upper surface side of the drift layer 2 in the breakdown voltage structure portion 102. In the ion implantation of the source region 6 and the channel stopper region 6c, the 4H-SiC structure on the upper surface side of the source region 6 is broken, forming an amorphous structure. The temperature in the ion implantation is set low to break the 4H-SiC structure. By performing the ion implantation of high-concentration impurities at a low temperature, the 4H-SiC structure can be broken. The temperature in the ion implantation is set to in a range of about 20° C. or more and less than 300° C., for example. The temperature boundary at which the 4H-SiC structure can be broken is around 300° C., and therefore the temperature in the ion implantation may be set to 200° C. or less, for example. The dose amount in the ion implantation is set to be about 2×10¹⁵ cm⁻² or more, for example. Thereafter, the mask pattern 22 is removed. The mask pattern 22 may be a hard mask pattern containing an oxide film, for example.

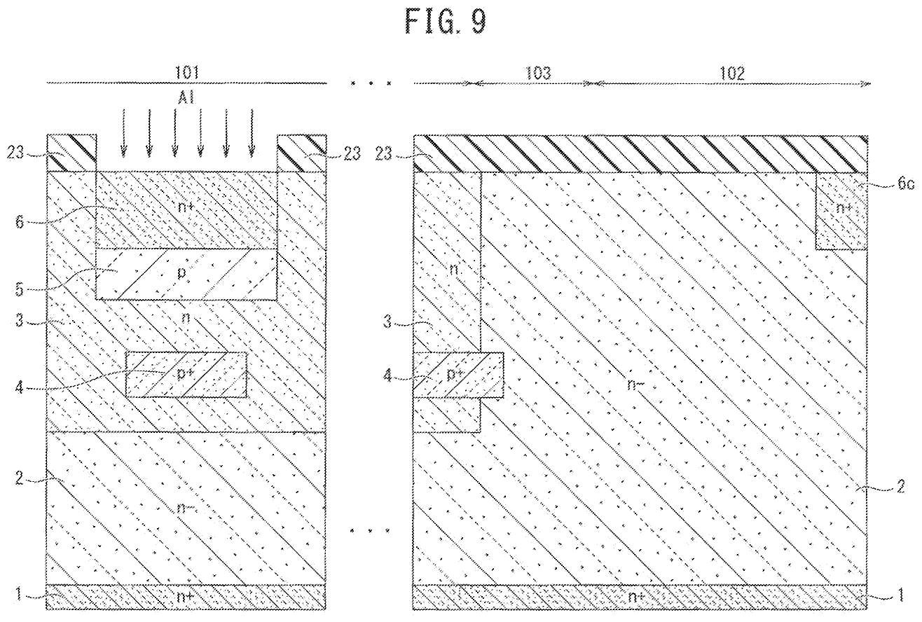

Next, a mask pattern 23 containing a photoresist film is formed on the upper surface of the drift layer 2 as illustrated in FIG. 9. Then, p-type impurities, such as aluminum (Al), are selectively ion-implanted using the mask pattern 23 as an ion implantation mask. As a result, the base region 5 is selectively formed on the upper surface side of the current spreading layer 3 and on the lower surface side of the source region 6 in the active portion 101 as illustrated in FIG. 9. The base region 5 is a region having the lowest impurity concentration among regions formed of p-type impurities. Thereafter, the mask pattern 23 is removed. The mask pattern 23 may be a hard mask pattern containing an oxide film, for example.

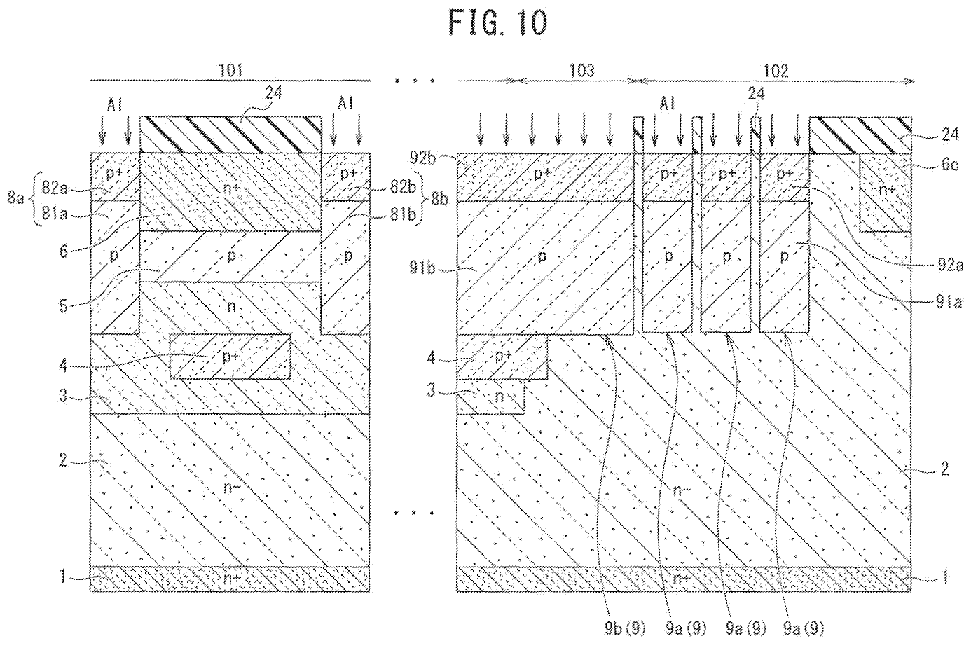

Next, the buried regions 81a, 81b, the base contact regions 82a, 82b, the electric field relaxation regions 9a, and the ring region 9b are formed as illustrated in FIG. 10. More specifically, the ion implantation in a step of forming the buried regions 81a, 81b and the base contact regions 82a, 82b and the ion implantation in a step of forming the electric field relaxation regions 9a and the ring region 9b are simultaneously performed. First, a mask pattern 24 constituted of a photoresist film is formed on the upper surface of the current spreading layer 3 using a photolithography technology. The mask pattern 24 may be a hard mask pattern containing an oxide film, for example. The mask pattern 24 has openings at positions where the base contact regions 82a, 82b are to be formed in the active portion 101, openings at positions where the electric field relaxation regions 9a are to be formed in the breakdown voltage structure portion 102, and an opening at a position where the ring region 9b is to be formed in the area 103.

Then, p-type impurities, such as aluminum (Al), are selectively ion-implanted using the mask pattern 24 as an ion implantation mask. By performing the ion implantation in multiple stages, the impurity concentration of the upper surface side of SiC is made higher than that at a deeper position. As a result, the buried regions 81a, 81b are formed to be in contact with the base region 5 on the upper surface side of the current spreading layer 3 in the active portion 101. Then, the base contact regions 82a, 82b are formed to be in contact with the source region 6 on the upper surface sides of the buried region 81a, 81b, respectively. The electric field relaxation regions 9a are formed on the upper surface side of the drift layer 2 in the breakdown voltage structure portion 102. The ring region 9b is formed on the upper surface side of the current spreading layer 3 in the area 103.

In the ion implantation described above, the 4H-SiC structures in partial regions of the upper surface side of SiC are broken, forming amorphous structures. More specifically, in the base contact regions 82a, 82b and the second parts 92a and 92b, the 4H-SiC structures in at least partial regions of the upper surface sides of SiC are broken, forming amorphous structures. The temperature in the ion implantation is set low to break the 4H-SiC structures, and is set to be in a range of about 20° C. or more and less than 300° C., for example. The dose amount in the ion implantation for the base contact regions 82a, 82b and the second parts 92a, 92b is set lower than the dose amount in the ion implantation for forming the source region 6 and the channel stopper region 6c, and is set to be in a range of about 1×10¹⁵ cm⁻² or more and less than 2×10¹⁵ cm⁻², for example. Due to the multiple-stage implantation, the impurity dose amount in the ion implantation for the buried regions 81a, 81b and the first parts 91a, 91b is set smaller than the impurity dose amount for the base contact regions 82a, 82b and the second parts 92a, 92b. This prevents 4H-SiC from being excessively broken. Thereafter, the mask pattern 24 is removed. The mask pattern 24 may be a hard mask pattern containing an oxide film, for example.

Next, an activation annealing (heat treatment) step is performed. In this activation annealing step, the activation annealing is performed at a temperature in a range of about 1600° C. or more and 1900° C. or less, for example, thereby simultaneously activating the p-type impurities or the n-type impurities ion-implanted into each of the gate bottom protection region 4, the base region 5, the source region 6, the buried regions 81a, 81b, the base contact regions 82a, 82b, the electric field relaxation regions 9a, the ring region 9b, and the like. At this time, the amorphous structure of at least a part of each of the source region 6, the base contact regions 82a, 82b, and the second parts 92a, 92b becomes 3C-SiC by recrystallization, forming the source region 6, the base contact regions 82a, 82b, and the second parts 92a, 92b containing 3C-SiC. The first parts 91a, 91b remain 4H-SiC even after recrystallization.

Herein, an example is illustrated in which the activation annealing is performed once after all the ion implantation steps, but the activation annealing may be performed several times individually after each ion implantation step. The ion implantation steps in FIGS. 6 to 10 may also be performed in different orders. It may be acceptable that, before the activation annealing, a cap film containing carbon (C) is formed, the activation annealing is performed after the execution of the covering with the cap film, and the cap film is removed after the activation annealing.

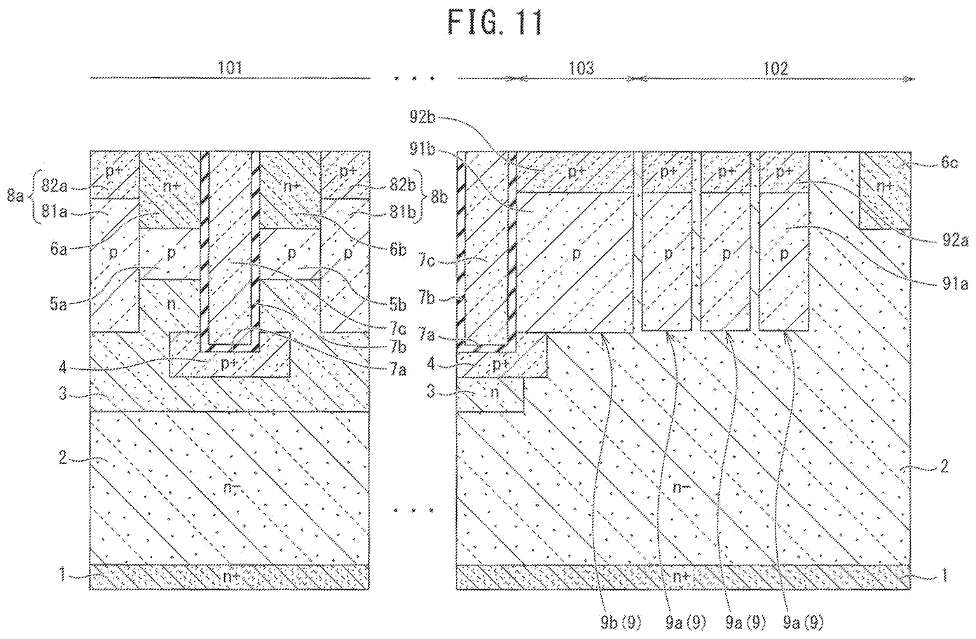

Next, a trench formation step is performed as illustrated in FIG. 11. In this trench formation step, a hard mask pattern containing an oxide film, for example, is formed on the upper surface of SiC using a photolithography technology, a dry etching technology, a CVD technology, and the like. The hard mask pattern has an opening at a position where the trench 7a is to be formed. Then, the trench 7a is selectively formed in the depth direction from the upper surface of the source region 6 by a dry etching technology, such as reactive ion etching (RIE), using the hard mask pattern as an etching mask. A photoresist film may be used in place of the hard mask pattern as the etching mask. The trench 7a passes through the source region 6 and the base region 5, and further digs through an upper portion of the current spreading layer 3 to reach the gate bottom protection region 4. The source region 6 is divided into the source regions 6a, 6b. The base region 5 is divided into the base regions 5a, 5b. Thereafter, the etching mask is removed.

Next, a gate insulating film/gate electrode formation step is performed. In the gate insulating film/gate electrode formation step, the gate insulating film 7b is formed on the lower surface and the side surfaces of the trench 7a by a CVD technology, a high temperature oxidation (HTO) method, a thermal oxidation method, or the like. Next, a polysilicon layer doped with impurities, such as phosphorus (P) or boron (B), with a high concentration (doped polysilicon layer) is deposited to fill the inside of the trench 7a by a CVD technology and the like. Thereafter, a part of the polysilicon layer and a part of the gate insulating film 7b are selectively removed by a photolithography technology and dry etching. This results in the formation of an insulated gate electrode structure (7b, 7c) containing the gate insulating film 7b and the gate electrode 7c as illustrated in FIG. 11.

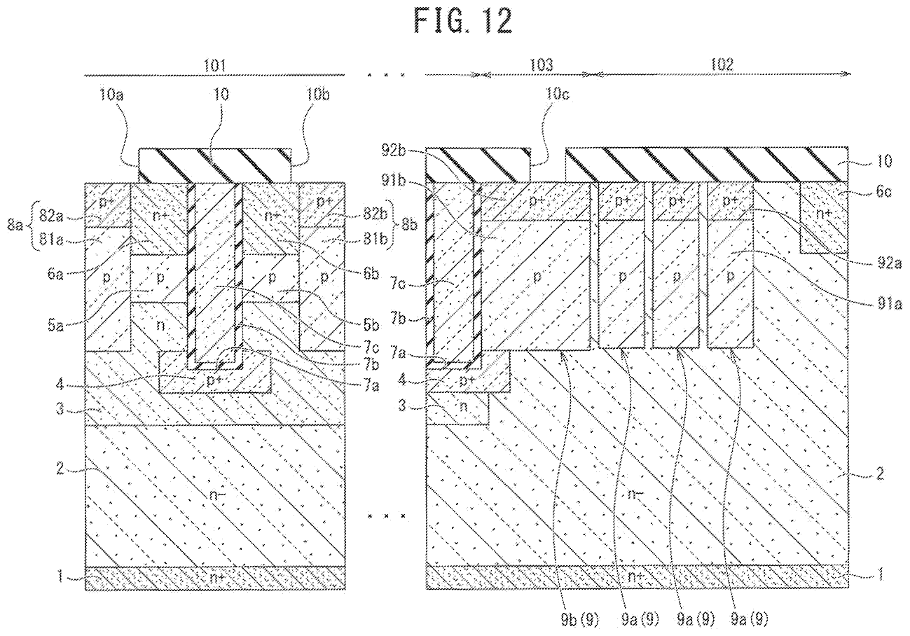

Next, the insulating film 10 is deposited on the upper surface of SiC by a CVD technology and the like as illustrated in FIG. 12. Then, a part of the insulating film 10 is selectively removed by a photolithography technology, a dry etching technology, and the like, opening the contact holes 10a, 10b exposing the upper surfaces of the source regions 6a, 6b and the base contact regions 82a, 82b, respectively, in the insulating film 10. Further, the contact hole 10c exposing the upper surface of the ring region 9b is opened. Thereafter, heat treatment (reflow) for flattening the insulating film 10 may be performed.

Next, the barrier metal layer 11 and the source wiring electrode 12 are sequentially formed to cover the upper surface and the side surfaces of the insulating film 10 and the upper surfaces of the source regions 6a, 6b, the base contact regions 82a, 82b, and the ring region 9b by a sputtering technology or a vapor deposition method, forming the source electrodes (11, 12) illustrated in FIG. 2. The barrier metal layer 11 is in contact with the source regions 6a, 6b, the base contact regions 82a, 82b, and the ring region 9b. The barrier metal layer 11 is in ohmic-contact with the source regions 6a, 6b, the base contact regions 82a, 82b, and the ring region 9b with low resistance.

Next, the SiC substrate 1 is thinned from the lower surface side by grinding, chemical mechanical polishing (CMP), or the like, thereby adjusting the thickness, so that the SiC substrate 1 serves as the drain region 1. Next, the drain electrode 13 (see FIG. 2) containing gold (Au) or the like is formed on the entire lower surface of the drain region 1 by sputtering, a vapor deposition method, or the like. This completes the SiC semiconductor device illustrated in FIG. 2.

According to the method for producing a SiC semiconductor device of the first embodiment, the step of forming the electric field relaxation regions 9a includes ion-implanting second conductivity-type impurities with a dose amount in a range of 1×10¹⁵ cm⁻² or more and less than 2×10¹⁵ cm⁻². Therefore, 3C-SiC can be formed in at least partial regions of the second parts 92a, and the resistance value of the second parts 92a can be increased. Thus, a current flowing when an avalanche occurs avoids the 3C-SiC part where the resistance value is high, and flows mainly in 4H-SiC located at a deeper position than the position of 3C-SiC. This can suppress the application of a large voltage to the insulating film 10 of the breakdown voltage structure portion 102, and suppresses the lowering of the reliability of the insulating film 10. The same applies also to the ring region 9b.

The step of forming the base contact regions 82a, 82b and the step of forming the electric field relaxation regions 9a include simultaneously ion-implanting second conductivity-type impurities with a dose amount in a range of 1×10¹⁵ cm⁻² or more and less than 2×10¹⁵ cm⁻². Since the ion implantation of each step is simultaneously performed, the number of steps can be reduced.

In the step of forming the source region 6a, 6b, first conductivity-type impurities are ion-implanted with a dose amount of 2×10¹⁵ cm⁻² or more, whereas the dose amount of the second conductivity-type impurities in the step of forming the second parts 92a of the electric field relaxation regions 9a is reduced to in a range of 1×10¹⁵ cm⁻² or more and less than 2×10¹⁵ cm⁻². This can lower the proportion of 3C-SiC contained in the second parts 92a than the proportion of 3C-SiC contained in each of the source regions 6a, 6b, increasing the proportion of 4H-SiC whose crystal defects fewer than those of 3C-SiC in the second parts 92a than that in each of the source regions 6a, 6b, thereby suppressing an increase in irregularities of the upper surfaces of the second parts 92a. Therefore, even when 3C-SiC has a larger number of crystal defects than those of 4H-SiC, the influence of 3C-SiC on the shape of the upper surfaces of the second parts 92a can be suppressed and an excessive increase in defects generated in the interface between the upper surfaces and the insulating film 10 can be suppressed. This can suppress the lowering of the reliability of the breakdown voltage structure portion 102. Further, in the step of forming the second parts 92a of the electric field relaxation regions 9a, the dose amount of the second conductivity-type impurities is reduced to in a range of 1×10¹⁵ cm⁻² or more and less than 2×10 cm⁻², and therefore the depth of the part with a high concentration of 3C-SiC can be kept shallow, and a region occupied by 4H-SiC having a band gap wider than that of 3C-SiC can be suppressed from decreasing more than necessary. The same applies also to the ring region 9b.

In the production method described above, the ion implantation of n-type impurities is performed, and then the ion implantation of p-type impurity is performed, but the ion implantation of p-type impurities may be first performed, and then the ion implantation of n-type impurities may be performed.

### Second Embodiment

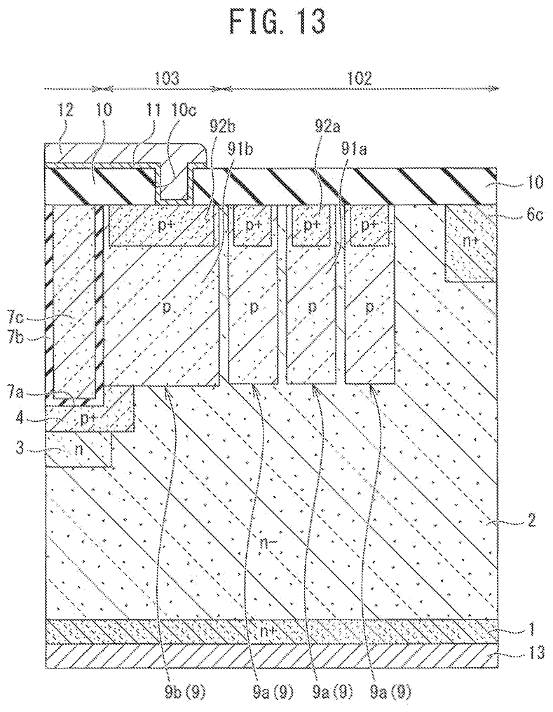

A SiC semiconductor device 100 according to a second embodiment is different in the configuration of the second parts 92a of the electric field relaxation regions 9a from the SiC semiconductor device 100 according to the first embodiment illustrated in FIG. 2. The second parts 92a according to the second embodiment each has the side surfaces and the bottom surface in contact with a part containing p-type 4H-SiC as illustrated in FIG. 13. More specifically, the second parts 92a each are in contact with the first parts 91a extending up to the upper surface side where the insulating film 10 is located. More specifically, the side surfaces and the bottom surface of each of the second parts 92a are covered with the first part 91a. Also the second part 92b of the ring region 9b is similarly in contact with the first part 91b extending up to the upper surface side where the insulating film 10 is located and has the side surfaces and the bottom surface covered with the first part 91b.

The shapes of such second parts 92a, 92b are not limited thereto, and can be formed by forming the openings of the mask pattern 24 illustrated in FIG. 10 into a shape widened upward as viewed in cross-section, for example.

In general, the electric field concentration is likely to occur at the boundary between n-type 4H-SiC and p-type 3C—SiC. According to the SiC semiconductor device 100 of the second embodiment, the first parts 91a are located between the second parts 92a and the current spreading layer 3 (drift layer 2), and therefore the direct contact of the second parts 92a containing p-type 3C-SiC with n-type 4H-SiC constituting the current spreading layer 3 (drift layer 2) is suppressed. This can suppress the electric field concentration and can suppress the lowering of the breakdown voltage performance of the electric field relaxation regions 9a even when the second parts 92a contain 3C-SiC. The same applies also to the ring region 9b.

### Third Embodiment

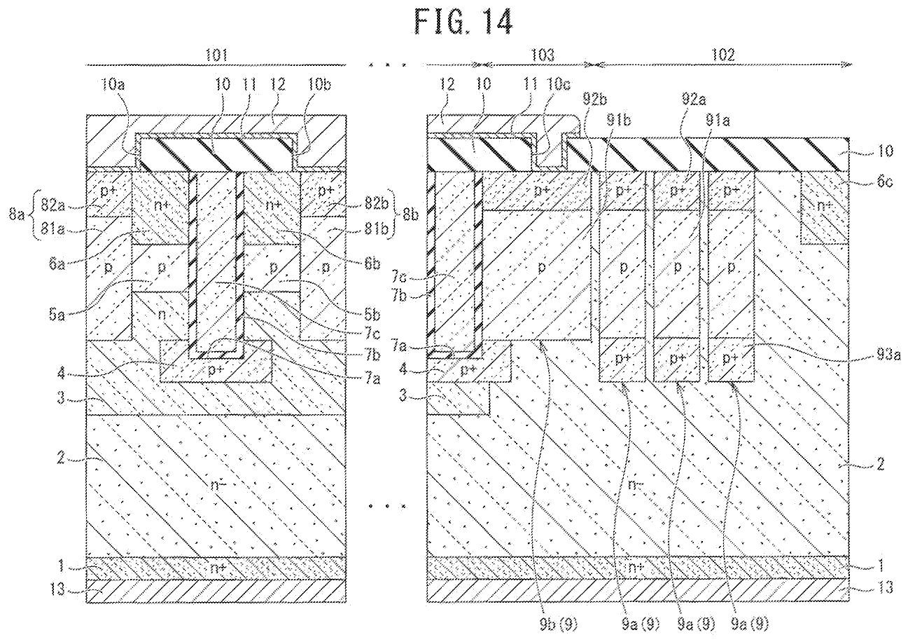

A SiC semiconductor device 100 according to a third embodiment is different in the configuration of the electric field relaxation regions 9a from the SiC semiconductor device 100 according to the first embodiment illustrated in FIG. 2. The electric field relaxation regions 9a according to the third embodiment contain, in addition to the first parts 91a and the second part 92a, second conductivity-type (p+-type) third parts 93a located at the same depth positions as that of the gate bottom protection region 4 and containing 4H-SiC as illustrated in FIG. 14.

The upper surfaces of the third part 93a are in contact with the lower surfaces of the first parts 91a. The third parts 93a can be formed simultaneously with the ion implantation of the gate bottom protection region 4 illustrated in FIG. 7. Therefore, the impurity concentration and the position in the depth direction of the third parts 93a are the same as the impurity concentration and the position in the depth direction of the gate bottom protection region 4.

Since the electric field relaxation regions 9a include the third parts 93a, a level difference in the depth direction step between the electric field relaxation regions 9a and the p-type region of the active portion 101 is reduced. This can further improve the breakdown voltage resistance performance of the electric field relaxation regions 9a.

### Other Embodiments

Although the first to third embodiments of this disclosure are described above, the discussion and the drawings forming part of this disclosure should not be understood as limiting this disclosure. Various alternative embodiments, examples, and operational technologies will be apparent to those skilled in the art from this disclosure.

For example, the MOSFET is illustrated as the semiconductor devices according to the first to third embodiments, but this disclosure is also applicable to an insulated-gate bipolar transistor (IGBT) having a configuration in which a p⁺-type collector region is provided in place of the n⁺-type drain region 1. Further, in addition to the IGBT alone, this disclosure is also applicable to a reverse conducting IGBT (RC-IGBT) or a reverse blocking insulated-gate bipolar transistor (RB-IGBT).

The first to third embodiments illustrate the case where the electric field relaxation regions 9a are the guard rings, but a JTE structure may be acceptable.

The configurations disclosed by the first to third embodiments may be combined as appropriate to the extent that no contradictions arise. Thus, it is a matter of course that this disclosure includes various embodiments and the like not described herein. Therefore, the technical scope of this disclosure is defined only by the matter specifying the invention according to claims reasonable from the description above.

“The first parts 91a, 91b contain 4H-SiC” means “The first parts 91a, 91b mainly composed of 4H-SiC”.

1. A silicon carbide semiconductor device comprising:
an active portion; and
a breakdown voltage structure portion provided surrounding a periphery of the active portion in plan view, wherein
a first conductivity-type drift layer containing silicon carbide is provided over the active portion and the breakdown voltage structure portion,
the active portion has:
a second conductivity-type base region containing silicon carbide provided on an upper surface side of the drift layer;
a first conductivity-type main region containing silicon carbide provided on an upper surface side of the base region;
a second conductivity-type buried region containing silicon carbide provided in contact with the base region on the upper surface side of the drift layer;
a second conductivity-type base contact region containing silicon carbide provided in contact with the main region on an upper surface side of the buried region;
a gate electrode provided with a gate insulating film interposed inside a trench passing through the main region and the base region; and
a main electrode provided in contact with the main region and the base contact region,
the breakdown voltage structure portion has:
a second conductivity-type electric field relaxation region containing silicon carbide provided on the upper surface side of the drift layer; and
an insulating film provided on an upper surface of the electric field relaxation region,
the main region and the base contact region each contain a 3C-structure in at least a part in contact with the main electrode, and
the electric field relaxation region contains a 3C-structure in an upper portion and contains a 4H-structure in a lower portion.

2. The silicon carbide semiconductor device according to claim 1, wherein the upper part of the electric field relaxation region and the base contact region each have a dimension in a depth direction of 0.3 μm or less.

3. The silicon carbide semiconductor device according to claim 1, wherein the upper part of the electric field relaxation region and the base contact region each contain a 3C-structure and a 4H-structure.

4. The silicon carbide semiconductor device according to claim 3, wherein a proportion of the 3C-structure contained in a part from the upper surface to a depth of 0.1 μm of the upper part of the electric field relaxation region and a proportion of the 3C-structure contained in a part from an upper surface to a depth of 0.1 μm of the base contact region each is in a range of 50% or more and 95% or less.

5. The silicon carbide semiconductor device according to claim 1, wherein the buried region contains a 4H-structure.

6. The silicon carbide semiconductor device according to claim 1, wherein the upper part of the electric field relaxation region has side surfaces in contact with a part containing a second conductivity-type 4H-structure.

7. The silicon carbide semiconductor device according to claim 1, wherein a plurality of the electric field relaxation regions is a plurality of guard rings provided in the breakdown voltage structure portion.

8. The silicon carbide semiconductor device according to claim 1, wherein the upper part of the electric field relaxation region has an impurity concentration in a range of 1×10¹⁹ cm⁻³ or more and 3×10²⁰ cm⁻³ or less.

9. The silicon carbide semiconductor device according to claim 8, wherein the base contact region has an impurity concentration in a range of 1×10¹⁹ cm⁻³ or more and 3×10²⁰ cm⁻³ or less.

10. The silicon carbide semiconductor device according to claim 1, wherein the main region has an impurity concentration in a range of 1×10²⁰ cm⁻³ or more and 3×10²¹ cm⁻³ or less.

11. The silicon carbide semiconductor device according to claim 1, comprising:
a second conductivity-type gate bottom protection region containing silicon carbide provided at a position in contact with a bottom of the trench, wherein
the electric field relaxation region includes a second conductivity-type region located at a same depth position as a depth position of the gate bottom protection region and contains silicon carbide.

12. A method for producing a silicon carbide semiconductor device comprising:
forming a first conductivity-type drift layer containing silicon carbide over an active portion and a breakdown voltage structure portion surrounding a periphery of the active portion in plan view;
forming a second conductivity-type base region containing silicon carbide on an upper surface side of the drift layer in the active portion;
forming a first conductivity-type main region on an upper surface side of the base region, the main region containing silicon carbide and containing a 3C-structure in at least an upper surface side part;
forming a second conductivity-type buried region containing silicon carbide to be in contact with the base region on the upper surface side of the drift layer;
forming a second conductivity-type base contact region to be in contact with the main region on an upper surface side of the buried region, the base contact region containing silicon carbide and containing a 3C-structure in at least an upper surface side part;
forming a trench passing through the main region and the base region;
forming a gate electrode with a gate insulating film interposed inside the trench;
forming a main electrode to be in contact with upper surfaces of the main region and the base contact region;
forming a second conductivity-type electric field relaxation region containing silicon carbide and containing 3C-structure in an upper portion and containing 4H-structure in a lower portion on the upper surface side of the drift layer in the breakdown voltage structure portion; and
forming an insulating film on an upper surface of the electric field relaxation region.

13. The method for producing a silicon carbide semiconductor device according to claim 12, wherein
the forming the electric field relaxation region includes ion-implanting a second conductivity-type impurity with a dose amount in a range of 1×10¹⁵ cm⁻² or more and less than 2×10 cm⁻².

14. The method for producing a silicon carbide semiconductor device according to claim 12, wherein
the forming the base contact region and the forming the electric field relaxation region include simultaneously ion-implanting a second conductivity-type impurity with a dose amount in a range of 1×10¹⁵ cm⁻² or more and less than 2×10¹⁵ cm⁻².

15. The method for producing a silicon carbide semiconductor device according to claim 12, wherein
the forming the main region includes ion-implanting a first conductivity-type impurity with a dose amount of 2×10¹⁵ cm⁻² or more.

16. The method for producing a silicon carbide semiconductor device according to claim 15, wherein the first conductivity-type impurity is phosphorus or nitrogen.

17. The method for producing a silicon carbide semiconductor device according to claim 13, wherein the second conductivity-type impurity is aluminum.
